(19) United States
(12) Patent Application Publication
(10) Pub. No.: US 2012/0086452 A1
(43) Pub. Date: Apr. 12, 2012

(54) RF COIL AND MAGNETIC RESONANCE IMAGING APPARATUS

(76) Inventors: Masayoshi Dohata, Tokyo (JP); Shinichiro Suzuki, Tokyo (JP); Manabu Mochizuki, Tokyo (JP)

(21) Appl. No.: 13/378,099

(22) PCT Filed: Jun. 21, 2010
(86) PCT No.: PCT/JP2010/060421

§ 371 Date: Dec. 14, 2011

(30) Foreign Application Priority Data
Jun. 24, 2009 (JP) 2009-149244

(51) Int. Cl. G01R 33/341

(52) U.S. Cl. 324/318

(57) ABSTRACT

It is an object of the present invention to provide an RF coil and an MRI apparatus capable of ensuring a wide imaging space and excellent in terms of allowing maintenance at the time of installation or failure. In order to do so, an RF coil of the present invention includes a cylindrical outer conductor and a plurality of rung conductors disposed inside the outer conductor along a circumferential direction of the outer conductor. In addition, each of the plurality of rung conductors is electrically connected to the outer conductor through a capacitor so as to form an electrical loop. The outer conductor is divided into a plurality of portions in the circumferential direction and is characterized in that the numbers of rung conductors disposed in at least two divided portions are different. In addition, an MRI apparatus of the present invention includes such an RF coil.

### TECHNICAL FIELD

The present invention relates to a magnetic resonance imaging (hereinafter, referred to as an “MRI”) apparatus and in particular, to an RF coil for transmitting a high-frequency magnetic field.

### BACKGROUND ART

An MRI apparatus excites the nuclear spins of atoms, which form the tissue inside a subject, by irradiating the subject with a high-frequency magnetic field after placing the subject, such as a human body, in a uniform static magnetic field generated by a static magnetic field magnet. Then, the MRI apparatus measures a nuclear magnetic resonance (hereinafter, referred to as “NMR”) signal generated when the excited nuclear spins relax and images the shapes or functions of the head, abdomen, limbs, and the like in a two-dimensional manner or in a three-dimensional manner. In the imaging, different phase encoding and different frequency encoding are given to NMR signals by the gradient magnetic field, and the NMR signals are measured as time series data. The measured NMR signals are reconstructed as an image by a two-dimensional or three-dimensional Fourier transform. Irradiating the subject with a high-frequency magnetic field or detecting an NMR signal from the subject is performed by a device called a high-frequency coil (hereinafter, referred to as an RF coil).

If RF coils are classified in terms of the usage conditions, they are largely divided into RF coils, which are mainly used for high-frequency magnetic field irradiation in a state fixed to a gantry formed by a static magnetic field magnet, a gradient magnetic field coil, and the like of an MRI apparatus, and RF coils, which are mainly used to receive an NMR signal in a state separated from the gantry.

The RF coils used in a state fixed to the gantry of the MRI apparatus are further divided into types called a birdcage type (for example, refer to NTL 1 and PTL 1) and a TEM type (for example, refer to PTL 2 and PTL 3) in terms of the shape of a coil pattern. Since they are characterized in that they have a sensitivity area over the entire wide range of the subject, they are called a volume coil. In particular, in a gantry structure of a tunnel type MRI apparatus, a static magnetic field magnet, a gradient magnetic field coil, an RF shield, and an RF coil are disposed in this order from the outside toward the inside of the tunnel in many cases. The RF coil (volume coil) used in a state fixed to the gantry is advantageous in that time and effort of the operator are saved since there is no need to replace the coil for every examination.

### CITATION LIST

### Patent Literature

[PTL 1] U.S. Pat. No. 5,986,454
[PTL 2] U.S. Pat. No. 5,557,247
[PTL 3] U.S. Pat. No. 5,886,596

### Non Patent Literature

[NPL 1] Cecil E. Hayes, et al., “An Efficient, Highly Homogeneous Radio frequency Coil for Whole-Body NMR Imaging at 1.5 T”, Journal of Magnetic Resonance 63: 622-628 (1985)

### SUMMARY OF INVENTION

### Technical Problem

As conditions required for the MRI apparatus in recent years, it has been required for a large person, a seriously-ill person, or a claustrophobic person to undergo the MRI test with an easy mind. In addition, it has been required for an operator, such as a doctor or a laboratory technician, to waste less time and effort for replacing the coil for every examination. In addition, there is demand for an apparatus which is low in initial investment when introduced or in which time and effort or cost required for maintenance is low.

In the conventional tunnel type MRI apparatus, however, the internal diameter of a tunnel (imaging space) in which the subject is placed is small and the length of the tunnel is large. For this reason, there is a problem in that a large person feels uncomfortable or a seriously-ill patient cannot move into the tunnel and it is not possible to perform examinations accordingly. In addition, when attaching/detaching an RF coil with a large diameter or an RF coil united with an RF shield to/from a gantry, the burden on the operator increases not only at the time of initial installation but also at the time of repair during failure or at the time of maintenance called a periodic check according to an increase in the size or weight of the RF coil. This leads to increased costs of introduction or maintenance.

Being able to extend the imaging space where the subject is placed without changing the external diameter of the RF coil fixed to the gantry in the tunnel type MRI apparatus and being able to realize the RF coil with a structure excellent in terms of allowing maintenance at the time of initial installation or repair are significant benefits for both the subject and the operator.

The present invention has been made in view of the above situation, and it is an object of the present invention to provide an RF coil and an MRI apparatus capable of ensuring a wide imaging space and excellent in terms of allowing maintenance at the time of installation or failure.

### Solution to Problem

In order to achieve the above-described object, an RF coil of the present invention includes a cylindrical outer conductor and a plurality of rung conductors disposed inside the outer conductor along a circumferential direction of the outer conductor. In addition, each of the plurality of rung conductors is electrically connected to the outer conductor through a capacitor so as to form an electrical loop, and the outer conductor is divided into a plurality of portions in the circumferential direction and the numbers of rung conductors disposed in at least two divided portions are different.

In addition, an MRI apparatus of the present invention includes: a static magnetic field magnet which has a cylindrical hollow space inside and generates a static magnetic field in an axial direction of the cylinder; a cylindrical gradient magnetic field coil disposed in the hollow space; and an RF coil disposed at the cylinder side of the gradient magnetic field coil. The RF coil includes a cylindrical outer conductor and a plurality of rung conductors disposed inside the outer conductor along a circumferential direction of the outer conductor. Each of the plurality of rung conductors is electrically connected to the outer conductor through a capacitor so as to form an electrical loop. In addition, the outer conductor is divided into a plurality of portions in the circumferential direction and the numbers of rung conductors disposed in at least two divided portions are different.

### Advantageous Effects of Invention

According to the RF coil and the MRI apparatus of the present invention, it is possible to provide an RF coil and an MRI apparatus capable of ensuring a wide imaging space and excellent in terms of allowing maintenance at the time of installation or failure.

### BRIEF DESCRIPTION OF DRAWINGS

FIG. 1 is a schematic external view of a tunnel type MRI apparatus related to the present invention.

FIG. 2 is a block diagram schematically showing the internal configuration of the MRI apparatus.

FIG. 3 is a view showing the configuration an RF coil related to the present invention which is provided in a hollow space of the MRI apparatus related to the present invention.

FIG. 4 is a view showing a case where a TEM type split coil having a cylindrical outer conductor of a first embodiment is installed inside a gantry, where FIG. 4(a) is a view schematically showing the internal structure when the gantry is viewed from the front and FIG. 4(b) is a view schematically showing the internal structure when the gantry is viewed from an angle.

FIG. 5 is a view showing one of segment portions which form the TEM type split coil of the first embodiment.

FIG. 6 is a view showing a guide portion for fixing a segment portion in a hollow space which forms a tunnel of the static magnetic field magnet, where FIG. 6(a) is a perspective view seen from an opening of the gantry and FIGS. 6(b) to 6(d) are enlarged views when each guide portion is seen from the front.

FIG. 7 is a view showing an example for fixing a segment portion in a hollow space of the static magnetic field magnet, where FIG. 7(a) is a view of the internal structure when only the inside TEM type split coil and the inside guide portion are extracted from the view of the gantry in FIG. 6, FIG. 7(b) is a view showing the extraction of an upper right segment portion in a state where the TEM type split coil and the guide portion are disposed in the hollow space of the static magnetic field magnet, and FIG. 7(c) is a view showing the extraction of a lower left segment portion.

FIG. 8 is a view showing a case where a trimmer capacitor is adjusted only by a segment portion, FIG. 8(a) is a view showing a case of adjusting a trimmer capacitor by accessing the trimmer capacitor in a state where a second segment portion is slightly pulled out, FIG. 8(b) is a view showing a case of adjusting a trimmer capacitor by accessing the trimmer capacitor in a state where the second segment portion is not pulled out, and FIG. 8(c) is a view showing a case of adjusting a trimmer capacitor only by a first segment portion in a state where the segment portion is removed from the gantry.

FIG. 9 is a view showing a surface on which a connection point between an outer conductor in a first segment portion and a ribbon-shaped conductor is present.

FIG. 10 is a view showing an example of a TEM type split coil having an elliptic cylindrical outer conductor of a second embodiment, where FIG. 10(a) is a perspective view of the TEM type split coil having the elliptic cylindrical outer conductor of the present embodiment and FIG. 10(b) is a view schematically showing the internal structure when a gantry is seen from the front when the TEM type split coil having the elliptic cylindrical outer conductor of the present embodiment is installed inside the gantry.

FIG. 11 is a view showing a case where a TEM type split coil having a rod-shaped conductor of a third embodiment is installed inside a gantry, where FIG. 11(a) is a view schematically showing the internal structure when the gantry is viewed from an angle and FIG. 11(b) is a view showing a case where a lower left segment portion is pulled out.

### DESCRIPTION OF EMBODIMENTS

Hereinafter, preferred embodiments of an MRI apparatus of the present invention will be described in detail according to the accompanying drawings. In addition, in all the drawings for explaining the embodiments of the present invention, the same reference numeral is given to those elements with the same function and repeated explanation thereof will be omitted.

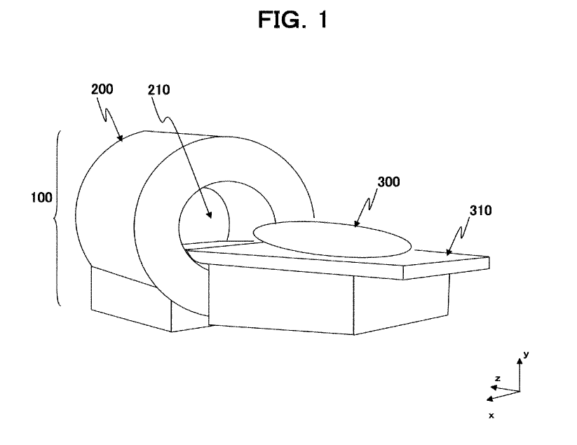

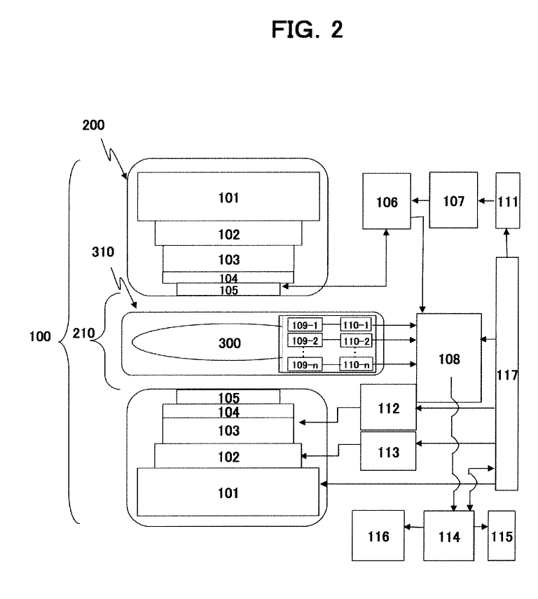

First, the outline of an example of an MRI apparatus related to the present invention will be described on the basis of FIGS. 1 and 2.

FIG. 1 is a schematic external view of an MRI apparatus 100 related to the present invention. This MRI apparatus 100 is a tunnel type MRI apparatus which examines a subject 300 by sliding and inserting a table 310, on which the subject 300 is placed, into a tunnel unit 210 which is a hollow space passing through a gantry 200.

FIG. 2 is a block diagram schematically showing the internal configuration of the MRI apparatus 100. Inside the gantry 200, there are provided: a static magnetic field magnet 101 which surrounds the tunnel unit 210, in which the subject 300 is placed, and which generates a static magnetic field in the axial direction of the tunnel unit 210; a shim coil 102 which generates a magnetic field for correction for optimizing the uniformity of the static magnetic field; a gradient magnetic field coil 103 which gives to the static magnetic field a magnetic field gradient in a predetermined direction; an RF coil 105 which transmits a high-frequency magnetic field, such as a radio (RF) wave, to the subject 300 and also receives an NMR signal from the subject; and an RF shield 104 which prevents interference between the gradient magnetic field coil 103 and the RF coil 105.

A transceiver switch 106 is connected to the RF coil 105. A power amplifier 107 which amplifies an RF signal from an RF pulse generator 111 and a receiver 108 which amplifies a received signal so as to have an optimal received signal level and performs analog-to-digital conversion are connected to the transceiver switch 106. In addition, although not shown, a synthesizer, a receiving mixer, an amplifier, an analog-to-digital converter, and the like are provided in the pulse generator 111 and the receiver 108.

In addition, apart from the RF coil 105, a receiving coil 109 is disposed near the subject 300. The receiving coil 109 includes “n” array coils 109-1 to 109-n and preamplifiers 110-1 to 110-n provided for the respective array coils. In addition, a shim power source 113 and a gradient magnetic field power source 112 for supplying a current are connected to the shim coil 102 and the gradient magnetic field coil 103, respectively.

In addition, a sequencer 117 which controls driving of the pulse generator 111, the receiver 108, the gradient magnetic field power source 112, and the shim power source 113, a calculator 114 which transmits various kinds of information processing and instruction processing from an operation of an operator to the sequencer 117, a storage medium 115 which stores a processing result, and a display 116 for displaying a processing result are provided.

In the MRI apparatus 100, the RF pulse generator 111, the receiver 108, the gradient magnetic field power source 112, and the shim power source 113 operate on the basis of a predetermined pulse sequence according to a command from the sequencer 117. The RF signal from the RF pulse generator 111 is amplified by the power amplifier 107, and an electromagnetic wave (RF pulse) is irradiated to the subject 300 in a static magnetic field and a gradient magnetic field through the transceiver switch 106 and the RF coil 105. The NMR signal from the subject 300 which is a response of the RF pulse is detected by the RF coil 105 and is transmitted to the receiver 108 and the calculator 114 through a preamplifier (not shown) in the transceiver switch 106, and appropriate signal processing is performed on the signal. As a result, an MR image and an MR spectrum are acquired. In addition, although an example using the RF coil 105 for both transmission and reception connected to the transceiver switch 106 in order to detect an NMR signal has been described herein, a receive-only coil 109 and a preamplifier 110 disposed near the subject 300 may also be used instead.

(Outline of the RF Coil of the Present Invention)

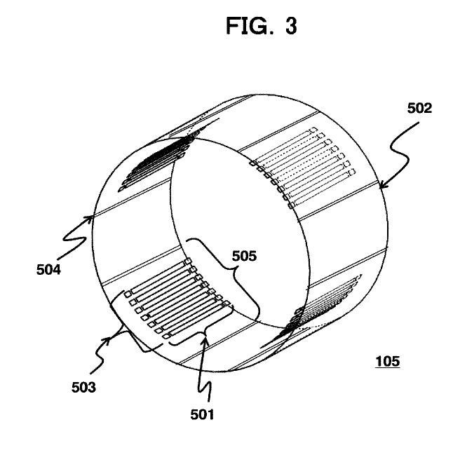

Next, the outline of the RF coil 105 of the present invention will be described on the basis of FIG. 3. The RF coil 105 shown in FIG. 3 is an RF coil used for transmission of an RF pulse and/or reception of an NMR signal, and is an example of a volume coil which can extend an internal space where a subject is placed without changing the external diameter for being fixed in a hollow space, which forms the tunnel 210 of the static magnetic field magnet 101, while maintaining sensitivity at the center of the tunnel 210.

This RF coil includes a cylindrical outer conductor and a plurality of rung conductors disposed inside the outer conductor along the circumferential direction of the outer conductor. Each of the plurality of rung conductors is electrically connected to the outer conductor through a capacitor so as to form an electrical loop. A power feeding point/power receiving point at which signal transmission and/or reception is performed is set between the cylindrical outer conductor and the rung conductor. In addition, at least two of the distances between the adjacent rung conductors in the circumferential direction are different from the other distances. In addition, it is preferable that each rung conductor be a long and narrow conductor, and the specific example will be described later through each embodiment.

More specifically, each rung conductor is disposed inside the cylindrical outer conductor so as to be parallel to the axial direction of the cylindrical outer conductor. In addition, a portion in which rung conductors are densely disposed and a portion in which rung conductors are sparsely disposed or there is no rung conductor (hereinafter, referred to as a sparsely disposed portion) are formed in the circumferential direction of the cylindrical outer conductor. That is, rung conductors are not disposed uniformly in the circumferential direction of the cylindrical outer conductor but disposed such that the arrangement distance or the arrangement density in the circumferential direction is different. In addition, in the portion in which rung conductors are sparsely disposed, there are a small number of rung conductors or there is no rung conductor. Accordingly, the portion in which rung conductors are densely disposed forms a group of rung conductors. In addition, in one portion in which rung conductors are densely disposed, each rung conductor and the cylindrical outer conductor are electrically connected to each other through a capacitor therebetween. Accordingly, the rung conductor and the cylindrical outer conductor are united to perform the same operation as a portion in which one element and the ground are connected to each other in a TEM type volume coil. As a result, a magnetic field component perpendicular to the central axis is generated at a desired resonance frequency in a cylinder.

By configuring the above-described volume coil such that the portions in which the rung conductors are sparsely disposed become left and right directions, that is, left and right directions of the subject when viewed from the axial direction of the cylindrical outer conductor, an empty space can be extended in the left and right directions inside the volume coil. As a result, the inside tunnel space can be extended in the left and right directions without enlarging the external diameter of the RF coil. Therefore, since it becomes possible to have spare space in the left and right directions of the subject who is long in the horizontal direction that is the left and right directions, it is possible to improve the comfort of the subject. In addition, by forming the portion in which the rung conductors are sparsely disposed in the vertical direction when seen from the axial direction of the cylindrical outer conductor, the inside tunnel space can be extended not only in the horizontal direction but also in the vertical direction. This can improve the comfort of the subject further.

In addition to the configuration described above, the RF coil of the present invention is configured such that the outer conductor is divided into a plurality of portions in the circumferential direction and the numbers of rung conductors disposed in at least two divided portions are different. A preferable division method is to divide the outer conductor into a portion in which rung conductors are densely disposed and a portion in which rung conductors are sparsely disposed. Hereinafter, such a coil is called a TEM type split coil, this TEM type split coil will be described as an example through each embodiment of the present invention.

### First Embodiment

Next, a first embodiment of the RF coil and the MRI apparatus of the present invention will be described. In the present embodiment, rung conductors are disposed inside a cylindrical outer conductor. Hereinafter, the present embodiment will be described in detail on the basis of the accompanying drawings using a ribbon-shaped conductor as an example of the rung conductor. However, the present embodiment is not limited to the ribbon-shaped conductor, and rung conductors with other shapes may also be used.

The RF coil 105 of the present embodiment provided in the gantry 200 of the MRI apparatus 100 is a TEM type split coil shown in FIG. 3 and includes a ribbon-shaped conductor 501, which is a thin plate-like conductor with predetermined length and width, and a cylindrical conductor 502 with a cylindrical shape serving as a ground plane.

A copper sheet is preferably used as the cylindrical conductor 502, and a copper mesh may also be used. Even if a copper mesh is used, a function as the ground plane is not affected. In addition, the cylindrical conductor 502 may also be realized by stainless steel or brass other than copper.

The ribbon-shaped conductor 501 is disposed along the inner surface of a cylinder which shares the central point axis of the cylindrical conductor 502. Moreover, the plurality of ribbon-shaped conductors 501 can be divided into a portion in which they are adjacent to each other densely and a portion in which they are sparsely disposed or there is no ribbon-shaped conductor 501. The portion in which the ribbon-shaped conductors are densely disposed, which is located apart from the portion in which the ribbon-shaped conductors are sparsely disposed, forms a conductor group 503. The portions in which the ribbon-shaped conductors are densely disposed are disposed at positions which are symmetrical with respect to the central axis of the cylindrical conductor 502. When viewed from the central axis direction, they are disposed at a diagonally upper right position (near approximately 45°), a diagonally lower right position (near approximately −45°), a diagonally upper left position (near approximately 135°), and a diagonally lower left position (near approximately 225°). In addition, the portions in which the ribbon-shaped conductors are sparsely disposed are disposed at left and right positions (near approximately 0° and near approximately 180°) and upper and lower positions (near approximately 90° and near approximately 270)°.

In addition, the cylindrical conductor 502 is divided in the circumferential direction with a dividing line 504 between adjacent groups as a boundary so that the group 503 of the ground plane corresponding to the portion in which the ribbon-shaped conductors 501 are densely disposed and a portion in which the ribbon-shaped conductors 501 are sparsely disposed is formed. As a result, the cylindrical conductor 502 has a plurality of arc surfaces 505. Specifically, as shown in FIG. 3, the cylindrical conductor 502 is divided into the arc surfaces 505 of eight regions by eight dividing lines 504 so that the ribbon-shaped conductors 501 are formed in four dense portions and four sparse portions. In addition, each conductor group 503 includes seven ribbon-shaped conductors 501.

In addition, the arrangement and the shape of the ribbon-shaped conductor of the present embodiment are not limited to the example shown in FIG. 3. For example, although ribbon-shaped conductors in a portion in which the ribbon-shaped conductors are disposed densely are disposed at equal intervals in FIG. 3, the distance between the ribbon-shaped conductors may not be equal. In addition, although the width of each ribbon-shaped conductor is equal in FIG. 3, the width may be different. In addition, the number of ribbon-shaped conductors 501 which form the conductor group 503 may not be seven, and one to six or eight to sixteen ribbon-shaped conductors 501 may be used.

In the TEM type split coil configured such that the portions in which the ribbon-shaped conductors 501 are sparsely disposed become horizontal and vertical directions using the conductor group 503 and the ground planes described above, maintaining almost the same central sensitivity compared with even a birdcage type volume coil or a TEM type volume coil with almost the same diameter is understood by computer simulation. In addition, since there is no element of the RF coil in the horizontal direction in which the portions, in which the ribbon-shaped conductor 501 are sparsely disposed, are present, it is possible to increase the opening width of a tunnel in the horizontal direction. Therefore, it is possible to improve the comfort of the subject in the horizontal direction.

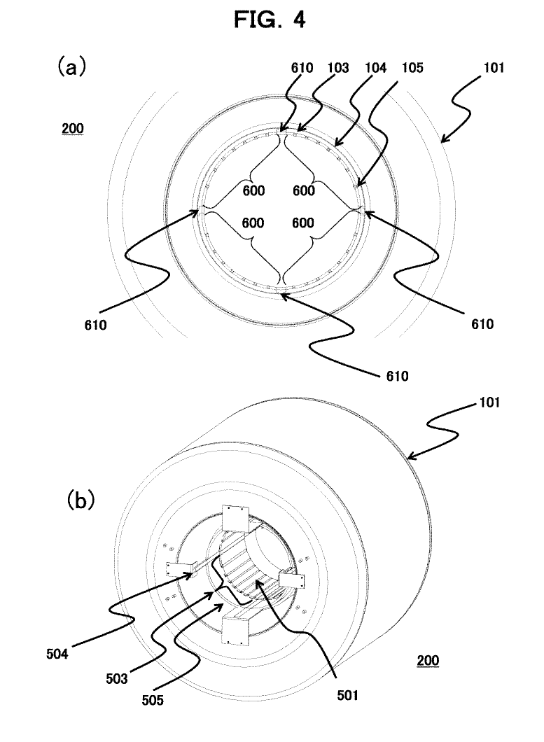

FIG. 4 is a view showing a case where the TEM type split coil of the present embodiment is installed inside a gantry. FIG. 4(a) is a view schematically showing the internal structure when the gantry 200 is viewed from the front, and FIG. 4(b) is a view schematically showing the internal structure when the gantry 200 is viewed from an angle.

The static magnetic field magnet 101, a shim coil (not shown), the gradient magnetic field coil 103, the RF shield 104, and the TEM type split coil of the present embodiment which is the RF coil 105 are provided in the gantry 200 in order from the outside of the tunnel toward the inside. As described above, in the TEM type split coil of the present embodiment, the outer conductor and the ribbon-shaped conductors are divided into a portion in which the conductor group 503 is present and a portion in which the conductor group 503 is not present by the dividing line 504. The portion in which the conductor group 503 is present forms one segment portion 600, and the portion in which the conductor group 503 is not present forms one guide portion 610. Accordingly, the TEM type split coil of the present embodiment is configured to include a plurality of segment portions 600 and a plurality of guide portions 610. That is, the TEM type split coil of the present embodiment is divided into the segment portion 600, which is formed by the integral structure of an outer conductor in a portion in which ribbon-shaped conductors are densely disposed and the ribbon-shaped conductors disposed densely, and the guide portion 610, which is a portion in which there is no ribbon-shaped conductor and which has an outer conductor. In addition, the segment portion 600 and the guide portion 610 are disposed alternately and repeatedly in the circumferential direction, and are fixed in the hollow space of the static magnetic field magnet 101.

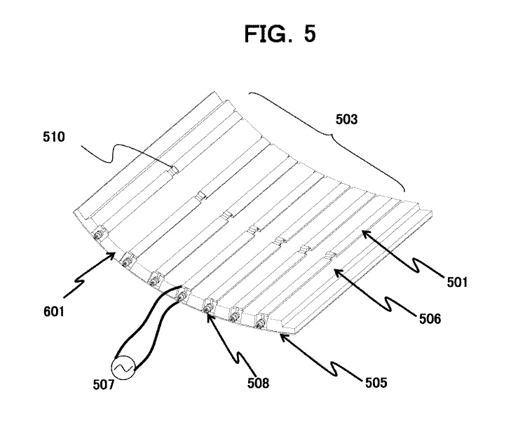

FIG. 5 is a view showing one of the segment portions 600 shown in FIG. 4. One segment portion 600 is formed by the conductor group 503 formed by the ribbon-shaped conductors 501, the arc surface 505 formed by division of the cylindrical conductor 502 functioning as a ground plane, and a resin material 506 between the ribbon-shaped conductor 501 and the arc surface 505. That is, the conductor group 503 including the ribbon-shaped conductors 501 is disposed on one surface (hollow space side of the static magnetic field magnet 101) of the resin material 506, the arc surface 505 of the conductor which is a ground plane is disposed on the other surface (bore wall surface side of the static magnetic field magnet 101), and the ribbon-shaped conductor 501 and the arc surface 505 are connected to each other at a connection point 508 to thereby form the segment portion 600. A dielectric with a dielectric constant of 1 or more may be used as the resin material 506.

An element, such as a capacitor, is disposed at the connection point 508. That is, a space is formed between the ribbon-shaped conductor 501 and the arc surface 505, and one loop is formed through the connection point 508 at which a capacitor or the like is disposed. By adjusting the value of the disposed capacitor, it is possible to match the input impedance and the resonance frequency of the segment portion 600 at a power feeding/power receiving point 507 to the characteristic impedance of a transmission cable or to make it resonate at a frequency matched to an NMR signal.

In addition, the ribbon-shaped conductor 501 may be divided by a capacitor 510. That is, the ribbon-shaped conductor 501 may have a configuration in which a plurality of divided conductors and capacitors are connected in series to each other.

A plurality of connection points 508 or one of the connection points 508 becomes a power feeding point for supplying power to the RF coil 105, that is, the segment portion 600 or a power receiving point for extracting a detected NMR signal to the receiver side, and serves as the power feeding/power receiving point 507 accordingly. In addition, in the case of forming the RF coil 105 shown in FIG. 3, the number of segment portions 600 becomes 4 and the number of power feeding/power receiving points 507 also becomes 4. In image imaging of the MRI, an electromagnetic wave may be supplied to the four power feeding points. In this case, the same waveform may be supplied to the four power feeding points by shifting the phase, or completely different waveforms may be supplied to the four power feeding points. In addition, the number of power feeding points is not necessarily equal to the number of segment portions, and the number of power feeding/power receiving points may be smaller than the number of segment portions.

By adjusting the segment portion 600 configured as described above for every segment portion 600, each segment portion 600 can be adjusted so as to resonate at the resonance frequency for acquiring an NMR signal.

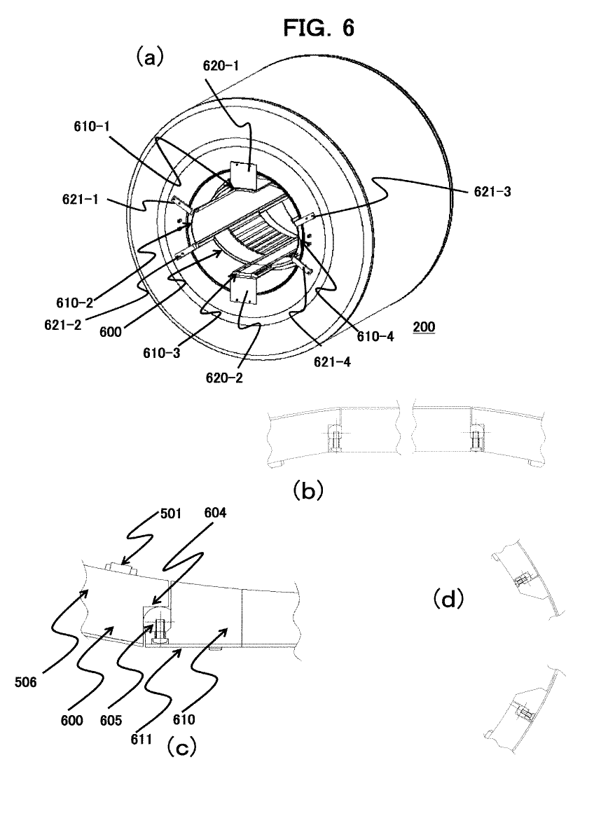

FIG. 6 is a view showing the guide portion 610 (610-1 to 610-4) for fixing the segment portion 600 in the hollow space which forms the tunnel 210 of the static magnetic field magnet 101. FIG. 6(a) is a perspective view seen from an opening of the gantry 200, and FIGS. 6(b) to 6(d) are enlarged views when each guide portion is seen from the front. In the present embodiment, the guide portion and the segment portion have structures fitting each other and are combined together, and the guide portion supports the segment portion slidably through the fitting structure.

The guide portion 610-1 is a guide disposed at the top in the hollow space, and the details are shown in FIG. 6(b). The guide portion 610-3 is a guide disposed at the bottom in the hollow space, and the details are shown in FIG. 6(c). The guide portion 610-4 is a guide disposed at the right side in the hollow space, and the details are shown in FIG. 6(d). The guide portion 610-2 is a guide disposed at the left side in the hollow space. Since the guide portions 610-2 and 610-4 are symmetrical, the guide portion 610-2 is not shown in the drawing.

Details of the guide portion will be described using as an example the guide portion 610-3 disposed at the bottom in the hollow space of the static magnetic field magnet 101 which is shown in FIG. 6(c). In the resin portion 506 which forms the segment portion 600, a groove 604 is cut at both ends in the circumferential direction. In the guide portion 610, a guide rail 605 is formed at both ends in the circumferential direction with resin of a different material (for example, POM (polyoxymethylene), polyacetal, or the like) from the resin portion 506. In addition, the groove 604 of the resin portion 506 and the guide rail 605 of the guide portion 610 are disposed in a state fitting each other, and the segment portion 600 slides on the guide rail 605 while rubbing on the guide rail 605 against the guide portion 610. As a result, the segment portion 600 is disposed at a predetermined position in the hollow space of the static magnetic field magnet 101. The guide rail 605 is fixed to the guide portion 610 by being screwed at a plurality of places from the arc surface 505 side at the end of the guide portion 610. In addition, the guide rail 605 may be bonded to the guide portion 610 without a screw. Thus, by forming the guide rail 605 with different resin from resin of a portion equivalent to the sliding surface of the segment portion 600, the frictional force generated at the time of sliding can be suppressed. As a result, it is possible to realize a structure excellent in terms of allowing maintenance.

In addition, although not shown, a mating connector may be provided in a contact portion in order to strengthen the cylindrical conductor 505 more.

Fitting portions of the groove 604 and the guide rail 605 have stepped shapes fitting each other, so that the segment portion 600 is supported without falling off the guide portion 610. Specifically, in the stepped shape shown in FIG. 6(c), a portion of the groove 604 of the resin portion 506 at the hollow space side protrudes toward the guide portion 610 and a portion at the arc surface 505 side is recessed toward the resin portion 506. On the other hand, in the guide portion 610-3, a portion at the hollow space side is recessed toward the guide portion 610 and a portion at the arc surface 505 side including the guide rail 605 protrudes toward the resin portion 506. This fitting structure with a stepped shape has the same structure at both ends of the guide portion 610-3. By such stepped shapes fitting each other, a protruding portion in the groove 604 of the resin portion 506 is supported by the guide rail 605 in a protruding portion of the guide portion 610-3 and the segment portion 600 slides along the guide rail 605.

In addition, an arc surface 611 at the outer side (static magnetic field magnet 101 side) of the guide portion 610 is formed of the same metal as the arc surface 505 of the segment portion 600 so that it operates as a ground plane integrally with the arc surface 505 of the segment portion 600. In addition, the arc surface 505 of the segment portion 600 and the arc surface 611 of the guide portion 610 are electrically connected to each other in a state where the segment portion 600 slides along the guide portion 610 to be disposed at a predetermined position. As a result, they function as a ground plane as a whole. As an example of electrical connection between arc surfaces, the arc surfaces are overlapped in a non-contact state so as to be coupled in a high-frequency manner. Alternatively, a structure is provided in which the arc surfaces are connected to each other by contact using the second segment portion 600-1 divided in a z direction which will be described later. In addition, a mating connector may be provided in a contact portion of the arc surfaces of a conductor, so that the entire cylindrical conductor is more strengthened by fixing the arc surfaces more strongly.

In addition, also in the upper guide portion 610-1 shown in FIG. 6(b), the same configuration as the guide portion 610-3 can be realized. That is, also in the upper guide portion 610-1, a groove of a segment portion and a guide rail of a guide portion are disposed in a state fit together, and the segment portion slides on the guide rail while rubbing on the guide rail with respect to the guide portion. As a result, the segment portion is disposed at a predetermined position in the hollow space of the static magnetic field magnet. In addition, the groove and the guide rail have stepped shapes fitting each other, so that the segment portion is supported without falling off the guide portion. The difference is that the relationship of the step-shaped projection or recess is reverse. That is, a groove of a resin portion of a segment portion at the hollow space side is recessed toward the resin portion, and a portion at the arc surface side protrudes toward the guide portion. On the other hand, in the guide portion, a portion at the hollow space side including the guide rail protrudes toward the resin portion, and a portion at the arc surface side is recessed toward the guide portion. In addition, similar to the arc surface of the lower guide portion 610-3, the arc surface at the outer side (static magnetic field magnet 101 side) of the upper guide portion 610-1 is also formed of the same metal as the arc surface of the segment portion so that it operates as a ground plane integrally with the arc surface of the segment portion. The arc surface at the outer side of the upper guide portion 610-1 is electrically connected to the arc surface of the segment portion.

In addition, also in the right guide portion 610-4 shown in FIG. 6(d), a fitting structure with a stepped shape is provided and moving the segment portion slidably to a predetermined position in the hollow space of the static magnetic field magnet along the guide portion is the same as in the upper and lower guide portions. The difference is that the specific step-shaped fitting structure is different from the upper and lower guide portions. Specifically, an upper fitting portion is the same as the stepped fitting structure in the upper guide portion 610-1 described above and has a structure obtained by rotating the fitting structure in the upper guide portion 610-1 by a predetermined angle (90°) clockwise with respect to the magnetic field center. On the other hand, a lower fitting portion is the same as the stepped fitting structure in the lower guide portion 610-3 described above and has a structure obtained by rotating the fitting structure in the lower guide portion 610-3 by a predetermined angle (90°) counterclockwise with respect to the magnetic field center.

In addition, similar to the arc surfaces of the upper and lower guide portions 610-1 and 610-3, the arc surface at the outer side (static magnetic field magnet 101 side) of the right guide portion 610-4 is also formed of the same metal as the arc surface of the segment portion so that it operates as a ground plane integrally with the arc surface of the segment portion. The arc surface at the outer side of the right guide portion 610-4 is electrically connected to the arc surface of the segment portion.

Since the left guide portion 610-2 and the right guide portion 610-4 described above are symmetrical with respect to the vertical plane passing through the magnetic field center, detailed explanation regarding the left guide portion 610-2 will be omitted.

Next, a support portion, which supports each guide portion from the static magnetic field magnet 101, at both ends of each guide portion in the cylinder axis will be described. As shown in FIGS. 4 and 6, the upper and lower guide portions 610-1 and 610-3 are connected to the side surface of the static magnetic field magnet 101 in the axial direction through support plates 620-1 and 620-2 with the same width as the guide portion, respectively. In addition, the right and left guide portions 610-2 and 610-4 are connected to the side surface of the static magnetic field magnet 101 in the axial direction through two support plates 621-1 and 621-2 and 621-3 and 621-4 with smaller widths than the support plates 620-1 and 620-2, respectively. Accordingly, each guide portion 610 is fixed to the magnet 101 and is also supported from the static magnetic field magnet 101. Preferably, in order to prevent vibration of the gradient magnetic field coil 103 from being directly transmitted to the guide portion 610 and the segment portion 600, each guide portion 610 is supported from the static magnetic field magnet 101 in a state where a gap is formed between each of the guide portion 610 and the segment portion 600 and the gradient magnetic field coil 103 so that the guide portion 610 and the segment portion 600 are not in contact with the gradient magnetic field coil 103. Accordingly, since the weight of the subject is directly applied to the upper and lower guide portions 610-1 and 610-3, it is necessary to make a strong structure for the support portion. For this reason, the upper and lower guide portions 610-1 and 610-3 are connected to each other with a support plate interposed therebetween, which is wide compared with a support portion in the horizontal direction. To the right and left guide portions 610-2 and 610-4, the weight of the subject is not directly applied. For this reason, since it is preferable to have strength enough to suppress a positional variation in the horizontal direction, a narrower support plate than the support plate in the vertical direction may be used for the right and left guide portions 610-2 and 610-4. Connections between each support plate, the static magnetic field magnet, and the guide portion may be made using a screw, for example. In addition, the support portion structure described above is the same at both ends of the guide portion in the cylinder axis direction, that is, at the front and back sides.

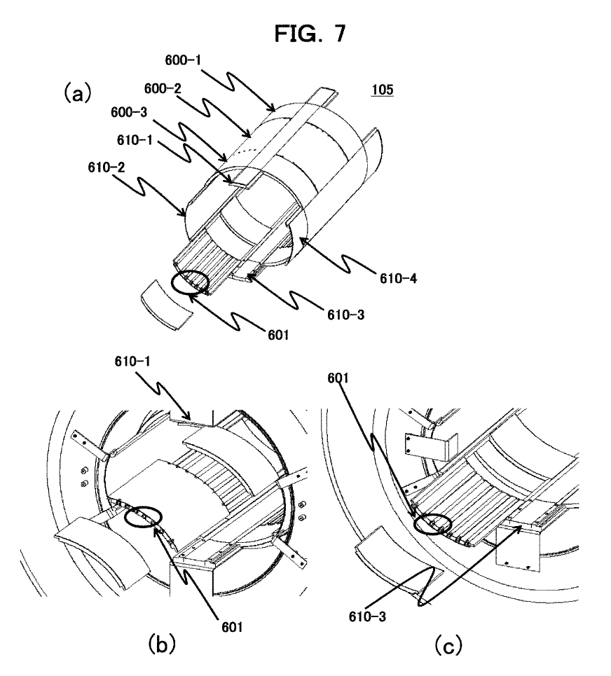

Next, fixing of the segment portion in the hollow space of the static magnetic field magnet will be described on the basis of FIG. 7. FIG. 7 is a view showing an example for fixing the segment portion 600 in the hollow space of the static magnetic field magnet. FIG. 7(a) is a view of an internal structure when only the inside TEM type split coil 105 and the inside guide portion 610 are extracted from the view of the gantry 200 in FIG. 6. FIG. 7(b) is a view showing the extraction of an upper right segment portion in a state where the TEM type split coil 105 and the guide portion 610 are disposed in the hollow space of the static magnetic field magnet, and FIG. 7(c) is a view showing the extraction of a lower left segment portion.

In FIG. 7, each segment portion 600 is divided into three portions in the cylinder axis direction (z-axis direction). That is, each segment portion is divided into a middle portion, in which ribbon-shaped conductors are disposed, and end portions, in which there is no ribbon-shaped conductor and which have an outer conductor, in the axial direction of the outer conductor. Specifically, each segment portion 600 is divided into a first segment portion (600-2), in which both the conductor group 503 including the ribbon-shaped conductors 501 and the arc surfaces 505 that is a ground plane are present, and two second segment portions (segment portion 600-3 at the front side and segment portion 600-1 at the back side), in which only the arc surface 505 that is a ground plane is present at the bore wall surface side of the static magnetic field magnet 101 of the resin portion. On the axis-direction end side surface of the first segment portion, the ribbon-shaped conductor and the arc surface (outer conductor) are connected to each other through a capacitor, as described above.

As a result of such division, each segment portion 600 is formed such that the second segment portion 600-1 (end portion), the first segment portion 600-2 (middle portion), and the second segment portion 600-3 (end portion) are disposed in order from the back in the static magnetic field magnet cavity. In addition, the fitting structure of the second segment portions 600-1 and 600-3 and the guide portion is the same as that for the first segment portion 600-2, and the second segment portions 600-1 and 600-3 slide along the guide portion to be disposed at predetermined positions.

FIGS. 7(a) and 7(c) show cases where the first and second segment portions are separately pulled out in order of 600-3, 600-2, and 600-1 from the front for the lower left segment portion. In addition, FIG. 7(b) shows a case where each divided segment portion is pulled out in order for the upper right segment portion.

In addition, it is assumed that the guide portion 600 is one body without being divided in the cylinder axis direction (z-axis direction).

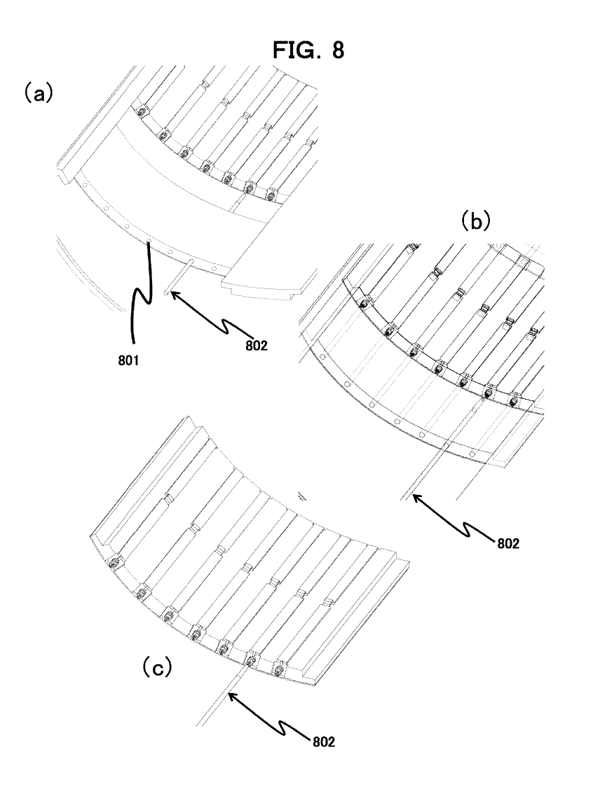

Next, a specific method of adjusting a trimmer capacitor will be described on the basis of FIG. 8. FIG. 8 is a view showing a case where a trimmer capacitor is adjusted only by a segment portion. FIGS. 8(a) and 8(b) are views showing a case of adjusting a trimmer capacitor by accessing the trimmer capacitor from the front surface (entrance of a tunnel) in a state where first and second segment portions are mounted in a gantry. FIG. 8(a) is a view showing a case of adjusting a trimmer capacitor by accessing the trimmer capacitor in a state where the second segment portion is slightly pulled out, and FIG. 8(b) is a view showing a case of adjusting a trimmer capacitor by accessing the trimmer capacitor in a state where the second segment portion is not pulled out. FIG. 8(c) is a view showing a case of adjusting a trimmer capacitor only by the first segment portion in a state where the segment portion is removed from the gantry.

Each of the second segment portions 600-1 and 600-3 has a plurality of through holes 801 formed in the cylinder axis direction (z-axis direction). This through hole 801 is formed so that an adjustment device (for example, a driver) 802 for adjusting the trimmer capacitor can be inserted thereinto and is provided, for every trimmer capacitor, at the same position as the trimmer capacitor of the first segment portion 600-2 in the circumferential direction. An operator adjusts a trimmer capacitor to a desired value by inserting the adjustment device 802 in this through hole 801 to access the trimmer capacitor. At the time of adjustment, it is possible to adjust the trimmer capacitor by accessing the trimmer capacitor from the front surface (entrance of a tunnel) in a state where the first and second segment portions are mounted in a gantry, as shown in FIGS. 8(a) and 8(b). In this case, it is possible to adjust the trimmer capacitor by accessing the trimmer capacitor after making the trimmer capacitor be seen in a state where the second segment portion is slightly pulled out as shown in FIG. 8(a), or it is also possible to adjust the trimmer capacitor by accessing the trimmer capacitor in a state where the second segment portion is not pulled out as shown in FIG. 8(a). Alternatively, as shown in FIG. 8(c), an operator may remove a segment portion from the gantry, extract only the first segment portion, and access the trimmer capacitor directly to adjust it.

By pulling out or extracting the segment portion 600 configured as described above from the gantry for each segment portion 600 to adjust the value of the capacitor (for example, a variable capacitor or a trimmer capacitor), it is also possible to adjust each segment portion at a place distant from the gantry with a strong magnetic field.

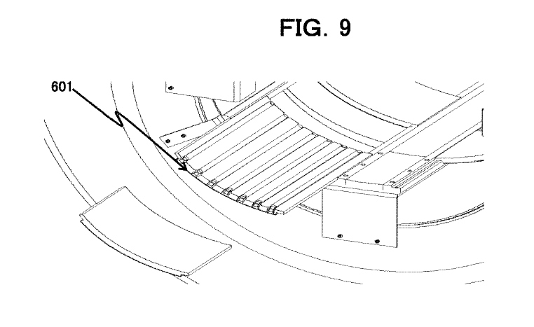

Next, connection between divided segment portions will be described on the basis of FIG. 9. As shown in FIG. 9 (also refer to FIGS. 5 and 7), also on a surface 601 on which the connection point 508 between an outer conductor in each first segment portion 600-2 and a ribbon-shaped conductor is present, that is, on a cylinder-axis-direction side surface of the resin portion between the outer conductor and the ribbon-shaped conductor, a conductor on the arc surface operating as a ground plane is extended and disposed in a portion in which neither the ribbon-shaped conductor nor the connection point 508 nor the power feeding/power receiving point is present. However, this extended conductor is connected to neither the ribbon-shaped conductor nor the connection point nor the power feeding/power receiving point. Similarly, a conductor on the arc surface operating as a ground plane is also extended and disposed on the opposite surface to the surface 601 in the second segment portions 600-1 and 600-3. Then, by electrically connecting these extended conductors to each other when installing the first segment portion 600-2 and the second segment portions 600-1 and 600-3 in the hollow space of the static magnetic field magnet, respective ground plane portions extended and disposed are fully connected in the z-axis direction in the hollow space and function as one ground plane eventually.

Originally, the outer conductor needs to serve as an RF shield for preventing interference between the ribbon-shaped conductor and the gradient magnetic field coil located outside. Accordingly, the length of the outer conductor in the longitudinal direction (z-axis direction) needs to be larger than the length of the ribbon-shaped conductor in the longitudinal direction (z-axis direction). For this reason, a hole structure passing through the middle resin portion is needed in order to connect the outer conductor and the ribbon-shaped conductor to each other. However, by adopting the structure in which the segment portion 600 is divided in the longitudinal direction (z-axis direction) as in the present embodiment, only the outer conductor serving as a ground plane can be connected on the dividing surface. Moreover, also in the divided state, electrical characteristics at the power feeding/power receiving point can be adjusted in units of a segment portion. Therefore, since it is not necessary to provide the hole structure, the manufacturing process can be simplified. In addition, the weight per segment portion can be reduced compared with a case where the hole structure is provided to connect the outer conductor and the ribbon-shaped conductor to each other.

Until now, the present embodiment has been described. Moreover, in the explanation of the present embodiment, the ribbon-shaped conductors are divided into a densely disposed portion and a sparsely disposed portion, and the ground plane is divided in the sparsely disposed portion to thereby form one segment portion. However, also in the case where the ribbon-shaped conductors are not divided into the densely disposed portion and the sparsely disposed portion, one segment portion may be formed by division in the ground plane portion to thereby form a groove and a guide portion.

As described above, according to the RF coil and the MRI apparatus of the present embodiment, since the plurality of ribbon-shaped conductors 501 are disposed densely and sparsely, they can be formed as an RF coil with a wide space horizontally and vertically. That is, it is possible to ensure a wide imaging space where the subject is placed. In addition, since a segment portion is disposed along the guide rail supported from the static magnetic field magnet by providing a groove by division in the sparsely disposed portion, it is possible to realize an RF coil excellent in terms of allowing maintenance. Therefore, the comfort of the subject placed inside the RF coil is improved. As a result, the RF coil which has improved maintenance efficiency for the operator or the installer so that the cost is reduced is realized.

### Second Embodiment

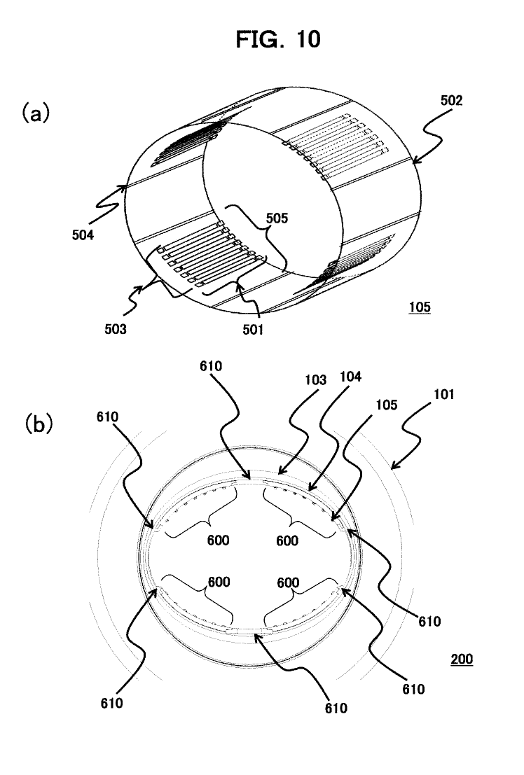

Next, a second embodiment of the RF coil and the MRI apparatus of the present invention will be described. In the present embodiment, ribbon-shaped conductors are disposed inside an elliptic cylindrical outer conductor. Hereinafter, only a different point of the present embodiment from the above first embodiment will be described in detail on the basis of FIG. 10.

FIG. 10 is a view showing an example of a TEM type split coil having an elliptic cylindrical outer conductor of the present embodiment. FIG. 10(a) is a view corresponding to FIG. 3(a) and is a perspective view of the TEM type split coil having an elliptic cylindrical outer conductor of the present embodiment. In addition, FIG. 10(b) is a view corresponding to FIG. 4(b) and is a view schematically showing the internal structure when the gantry 200 is seen from the front when the TEM type split coil having the elliptic cylindrical outer conductor of the present embodiment is installed inside the gantry.

Unlike the TEM type split coil having the cylindrical outer conductor shown in FIGS. 3 and 4 described in the first embodiment, the TEM type split coil of the present embodiment has an elliptic cylindrical outer conductor. Therefore, since each ribbon-shaped conductor is disposed along the inside of the outer conductor, each ribbon-shaped conductor in the TEM type split coil of the present embodiment is disposed in parallel to the focal axis on the inner surface of the elliptic cylinder so that the focal axis of the elliptic cylinder is shared.

In addition, positions at which ribbon-shaped conductors are disposed densely are disposed at a diagonally upper right position, a diagonally lower right position, a diagonally upper left position, and a diagonally lower left position when viewed from the focal axis direction of the elliptic cylinder, similar to the first embodiment described above. On the other hand, positions at which ribbon-shaped conductors are sparsely disposed become top, bottom, left, and right positions when viewed from the focal axis direction of the elliptic cylinder, similar to the first embodiment described above. As a result, it becomes possible to extend horizontally and vertically the space where the subject is placed.

In addition, each segment portion 600 and each guide portion 610 also have an elliptic arc shape. In particular, the bore wall surface sides of the static magnetic field magnet 101 of these become elliptic arc surfaces.

Others are the same as the first embodiment described above. Therefore, since the meaning and function of each portion shown in FIG. 9 are the same as each corresponding section in FIGS. 3 and 4, the same reference numerals are given. Explanation regarding each section to which the same reference numeral is given will be omitted.

In order to form an outer conductor with an elliptic cylinder shape, it is preferable that an opening of the gradient magnetic field coil disposed at the outside of the TEM type split coil also be formed in an elliptic shape having a long axis in the horizontal direction, that is, such that a cross section of an inside hollow portion of the gradient magnetic field coil becomes an elliptic shape having a long axis in the horizontal direction. When using a self-shielded gradient magnetic field coil including a main coil and a shield coil in order to do so, it is preferable to form the main coil disposed inside with an elliptic cylinder shape having a long axis in the horizontal direction. By forming the main coil with an elliptic cylinder shape, the TEM type split coil of the present embodiment can be disposed inside the main coil. Accordingly, since the spatial efficiency is increased, it is possible to improve the openness of a horizontally long subject in the horizontal direction. In addition, since the main coil can be brought close to the subject, a large gradient magnetic field can be generated with a low current. Therefore, the size of the gradient magnetic field power source can be reduced.

On the other hand, the shield coil disposed outside may have either an elliptic cylinder shape or a cylindrical shape. In particular, by forming the shield coil with a cylindrical shape and the main coil with an elliptic cylinder shape having a long axis in the horizontal direction, a distance between the main coil and the shield coil in the vertical direction is increased. Accordingly, the gradient magnetic field generation efficiency is improved. As a result, it is possible to generate a high-intensity gradient magnetic field with a low current compared with a gradient magnetic field coil in which both a main coil and a shield coil have cylindrical shapes.

As described above, according to the TEM type split coil having the elliptic cylindrical outer conductor of the present embodiment, it becomes possible to extend horizontally and vertically the space where the subject is placed, similar to the first embodiment described above. As a result, the comfort of the subject can be improved. In addition, by forming the main coil of the gradient magnetic field coil with an elliptic cylinder shape and the shield coil with an elliptic cylinder shape or a cylindrical shape, the gradient magnetic field generation efficiency can be improved. As a result, it is possible to generate a high-intensity gradient magnetic field with a small and low-capacity gradient magnetic field power source.

### Third Embodiment

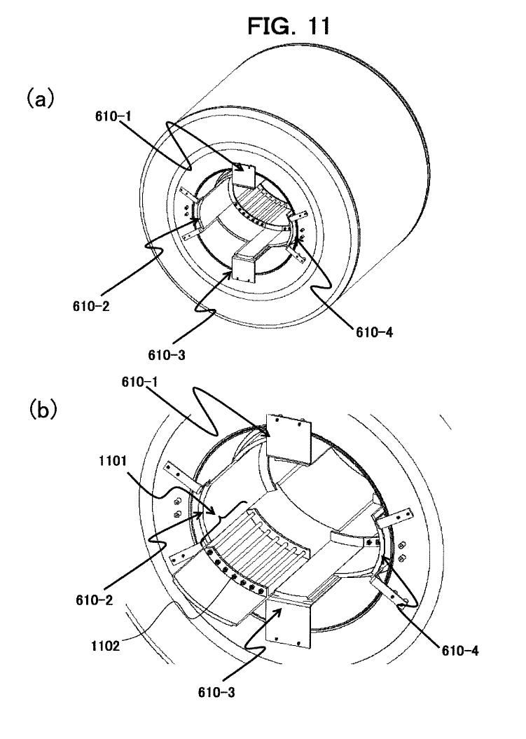

Next, a third embodiment of the RF coil and the MRI apparatus of the present invention will be described. In the present embodiment, a rod-shaped conductor is used as a rung conductor. Hereinafter, only a different point of the present embodiment from the above first embodiment will be described in detail on the basis of FIG. 11. In addition, the shape of an outer conductor of the present embodiment may be the same cylindrical shape as in the first embodiment described above or may be the same elliptic cylinder shape as in the second embodiment.

FIG. 11 shows a TEM type split coil having a rod-shaped conductor of the present embodiment. FIG. 11 is a view showing a case where the TEM type split coil of the present embodiment is installed inside a gantry. FIG. 11(a) is a view schematically showing the internal structure when the gantry 200 is viewed from an angle, and FIG. 11(b) is a view showing a case where a lower left segment portion is pulled out. In addition, FIG. 11 shows a case where an outer conductor has an elliptic cylinder shape. However, the outer conductor may have a cylindrical shape.

In the present embodiment, a TEM type split coil is formed using a rod-shaped conductor 1101 instead of the ribbon-shaped conductor 501 in the segment portion 600 in the case of the elliptic cylindrical outer conductor shown in FIG. 9. Each rod-shaped conductor 1101 is connected to a support portion 1102 at both ends. The support portion 1102 supports a plurality of rod-shaped conductors, which form each segment portion, collectively in units of a segment portion from the elliptic arc surface of a conductor serving as a ground plane. This support portion 1101 includes a path, which electrically connects each rod-shaped conductor and the elliptic arc surface of the conductor to each other through a capacitor, and the capacitor. Here, each rod-shaped conductor is fixed so that the rod-shaped conductors are electrically insulated from each other.

Alternatively, the rod-shaped conductor may be a coaxial line. In this case, an internal conductor of the coaxial line functions as a rung conductor. On the other hand, an external conductor of the coaxial line is connected to the elliptic arc surface of a conductor, which is an outer conductor, and functions as a ground plane. In this case, the support portion 1102 supports the coaxial line and also includes a path, which electrically connects the external conductor of the coaxial line and the elliptic arc surface that is a conductor to each other through a capacitor, and the capacitor. If the capacitor is a trimmer capacitor which can be adjusted, it is disposed on the support portion 1102. In this case, the capacitor may be adjusted by direct access, or the segment portion may be pulled out to adjust the capacitor.

As described above, by using the rod-shaped conductor and also dividing the ground plane in a portion in which there is no rod-shaped conductor, it is possible to form a TEM type split coil excellent in terms of allowing maintenance similar to the effect of each embodiment described above.

As described above, also in the TEM type split coil having the rod-shaped conductor element of the present embodiment, the same effect as in the first embodiment described above is obtained, and it becomes possible to make a rung conductor stronger than a ribbon-shaped conductor.

### REFERENCE SIGNS LIST

100: tunnel type MRI apparatus body
101: static magnetic field magnet
102: shim coil
103: gradient magnetic field coil
104: RF shield
105: transceiver coil
106: transceiver switch
107: RF power amplifier
108: receiver
109: receiving coil
110: preamplifier
111: RF pulse generator
112: gradient magnetic field power source
113: shim power source
114: calculator
115: storage medium
116: display
117: sequencer
200: gantry
210: opening surface
300: subject (object to be examined)
310: table
501: ribbon-shaped conductor
502: cylindrical conductor
503: conductor group
504: dividing line
505: shield arc surface
506: resin portion
507: power feeding/power receiving portion
508: connection point
600: segment portion
601: surface with a connection point in a segment portion
604: groove provided in a resin portion
605: guide rail portion
610: guide portion
611: arc surface in a guide portion
801: rod-shaped element and a segment portion formed by a rod-shaped element

1. An RF coil used for transmission of a high-frequency magnetic field and/or reception of a nuclear magnetic resonance signal, comprising:
a cylindrical outer conductor; and
a plurality of rung conductors disposed inside the outer conductor along a circumferential direction of the outer conductor,
wherein each of the plurality of rung conductors is electrically connected to the outer conductor through a capacitor so as to form an electrical loop, and
the outer conductor is divided into a plurality of portions in the circumferential direction and the numbers of rung conductors disposed in at least two divided portions are different.

2. The RF coil according to claim 1,
wherein at least two of distances between the adjacent rung conductors in the circumferential direction are different from the other distances.

3. The RF coil according to claim 1,
wherein the outer conductor is divided into a portion in which the rung conductors are densely disposed and a portion in which the rung conductors are sparsely disposed or there is no rung conductor.

4. The RF coil according to claim 3,
wherein the portion in which the rung conductors are sparsely disposed or there is no rung conductor is disposed in left and right directions when viewed from an axial direction of the outer conductor.

5. The RF coil according to claim 3,
wherein the RF coil is divided into a segment portion, which is formed by combination of the outer conductor in the portion in which the rung conductors are densely disposed and the rung conductors disposed densely, and a guide portion, which is a portion in which there is no rung conductor and which has the outer conductor.

6. The RF coil according to claim 5,
wherein the segment portion and the guide portion are disposed alternately and repeatedly in the circumferential direction.

7. The RF coil according to claim 4,
wherein the guide portion and the segment portion have structures fitting each other and are combined together, and
the guide portion supports the segment portion slidably through the fitting structure.

8. The RF coil according to claim 4,
wherein the segment portion is divided into a middle portion, in which the rung conductors are disposed, and end portions, in which there is no rung conductor and which have the outer conductor, in the axial direction of the outer conductor.

9. The RF coil according to claim 8,
wherein in the middle portion of the segment portion, the rung conductor and the outer conductor are connected to each other through the capacitor on the axis-direction end side surface of the middle portion.

10. The RF coil according to claim 8,
wherein in the middle portion of the segment portion, an extended conductor extending from the outer conductor is disposed at the axis-direction end of the middle portion, and
the extended conductor is electrically connected to the outer conductor at the end.

11. The RF coil according to claim 1,
wherein the outer conductor has a cylindrical shape.

12. The RF coil according to claim 1,
wherein the outer conductor has an elliptic cylinder shape.

13. The RF coil according to claim 1,
wherein the rung conductor is a ribbon-shaped or rod-shaped conductor.

14. A magnetic resonance imaging apparatus comprising:
a static magnetic field magnet which has a tunnel-like hollow space inside and generates a static magnetic field in an axial direction of the tunnel;
a cylindrical gradient magnetic field coil disposed in the hollow space; and
an RF coil disposed inside the gradient magnetic field coil,
wherein the RF coil includes a cylindrical outer conductor and a plurality of rung conductors disposed inside the outer conductor along a circumferential direction of the outer conductor,
each of the plurality of rung conductors is electrically connected to the outer conductor through a capacitor so as to form an electrical loop, and
the outer conductor is divided into a plurality of portions in the circumferential direction and the numbers of rung conductors disposed in at least two divided portions are different.

15. The magnetic resonance imaging apparatus according to claim 14,
wherein the RF coil is divided into a segment portion, which is formed by combination of the outer conductor in a portion in which the rung conductors are densely disposed and the rung conductors disposed densely, and a guide portion, which is a portion in which there is no rung conductor and which has the outer conductor,
the guide portion and the segment portion have structures fitting each other and are combined together, and
the guide portion supports the segment portion slidably through the fitting structure and also has a portion connected to the static magnetic field magnet so as to be supported from the static magnetic field magnet in a state not in contact with the gradient magnetic field coil.
